(19) United States
(12) Patent Application Publication
(10) Pub. No.: US 2007/0035215 A1
(43) Pub. Date: Feb. 15, 2007

(54) Substrate having polarized adhesive

(76) Inventor: Steven N. Kruchko, Western Springs, IL (US)

Correspondence Address: MCANDREWS HELD & MALLOY, LTD, 500 WEST MADISON STREET, SUITE 3400, CHICAGO, IL, 60661, US

(21) Appl. No.: 11/502,847

(22) Filed: Aug. 11, 2006

Related U.S. Application Data
(60) Provisional application No. 60/707,405, filed on Aug. 11, 2005.

(51) Int. Cl. H01L 41/00

(52) U.S. Cl. 310/348

(57) ABSTRACT

A surface cover having a polarized adhesive material bonded or operably connected to at least a portion of a substrate. The polarized adhesive material may be hot melt adhesive material. The substrate may have little or no electret capabilities. The electrostatic charge of the polarized adhesive material may allow the surface cover to be removed from a mounting surface for positional adjustment during the application of the surface cover to the mounting surface. Once at its desired location, and/or aligned with the patterns, characters, or images on an adjacent surface cover, the polarized adhesive material may be activated. The adhesive force provided by the activated polarized adhesive material may provide a sufficient force for adhering surface cover along the mounting surface, thereby making the dissipation or loss of electrostatic charge inconsequential to the ability of the surface cover to remain at its desired position along the mounting surface.

### RELATED APPLICATIONS

This application claims the benefit of U.S. Provisional Application No. 60/707,405, filed Aug. 11, 2005, which is incorporated herein by reference in its entirety.

### BACKGROUND OF THE INVENTION

Embodiments of the present invention generally relate to a surface cover that includes at least one substrate and a polarized adhesive material, the polarized adhesive material being bonded, embedded, or operably connected to the substrate. The use of a polarized adhesive material may at least temporarily assist with the positioning and eventual attachment or securing of the surface cover, such as wallpaper, borders, and decals, at a desired location on an adjacent mounting surface before the activation of the adhesive material.

Many common films and substrates (hereinafter collectively referred to as “substrates”) have an adhesive material bonded or operably connected to the backside surface of the substrate to create a surface cover. Examples of such surface covers may include wallpaper, borders, and decals, among others. But in the past, these surface covers have typically required that the adhesive material be activated before the substrate will adhere to an adjacent mounting surface at a desired location. For example, the glue adhesives that are commonly used with wallpaper typically must be wetted before the wallpaper can adhere to a wall at its desired location. Other types of adhesive materials require activation by the exposure of the adhesive material before the substrate may be positioned and secured to a mounting surface, such as through the removal of backing strips. Once the adhesive material has been activated, and the substrate has been secured against the adjacent mounting surface, subsequent attempts at adjust or move the placement of the surface cover may either be very difficult, damage the ability of the adhesive material to adhere to the mounting surface, and/or damage or destroy the substrate.

Further, having to activate the adhesive material before the surface cover will at least temporarily remain at or around a desired location on the adjacent mounting surface often makes precise positioning of such surface covers, or aligning the patterns or images on the substrate with those on neighboring substrates, difficult. For instance, common wallpaper has traditionally been difficult and cumbersome to install because, after wetting, the adhesive material on the back of the wallpaper may begin to set before the installer has time to properly align the printed patterns on the substrate with those on a neighboring strip of wallpaper. Additionally, wall boarders that incorporate pressure sensitive adhesive material often suffer from similar difficulties and problems in that once the adhesive material is activated, adjustments or realignment of the border often ruins at least a portion of the substrate. The difficulty in properly installing such surface covers often results in misaligned and/or torn or ruined substrates, which may increase material costs and justify the high cost of professional installation.

In an attempt to overcome such difficulties, some substrates are electrostatically polarized so that the substrate will adhere to an adjacent mounting surface without the need for an adhesive material. Such substrates utilize differences between the polarities of the substrate and the mounting surface to create an adhering bond that may allow the substrate to adhere to an adjacent mounting surface without the use of an activated adhesive material. The absence of an activated adhesive material may allow a polarized substrate that is placed along an adjacent mounting surface to be subsequently removed from that surface. The polarized substrate may then be reapplied to the same adjacent mounting surface, thereby allowing for the position and/or alignment of the substrate to be adjusted, without having to deal with the complications that are commonly associated with attempting to move surface covers that have activated adhesive material.

Yet, the ability to relatively easily remove or adjust the position of polarized substrates that do not use an adhesive material may also allow for accidental positional adjustments that may occur through inadvertent contact with the substrate. Further, the polarized charge may need to be sufficiently strong so as to support the weight of the entire substrate. Over time, the substrate may also at least partially lose its electrostatic charge. For instance, the presence of elevated temperatures and humidity may assist in the at least partial dissipation of the electrostatic charge. Dissipation of the electrostatic charge may cause the substrate to lose its adhesive connection with the adjacent mounting surface, which may result in the surface cover sagging or eventually falling or slipping from its position on a mounting surface.

In the past, one solution to this problem has been to attach a non-polarized adhesive material to a polarized substrate. In such devices, the adhesive force used to adhere the substrate to an adjacent mounting surface is created by both the polarized charge of the substrate and the activation of the adhesive material. Thus, in such systems, the electrostatic charge may be an integral part of the substrate being able to remain adhered to the adjacent mounting surface, even after the adhesive material has been activated.

Yet, as previously mentioned, over time, the polarized charge of the substrate may dissipate, which may reduce the strength of the adhesive connection between the substrate and the adjacent wall. Further, such apparatuses may be limited to use with substrates that have electret capabilities. Additionally, electrostatically charged or chargeable substrates may also create additional manufacturing and handling disadvantages.

In past situations in which a substrate has not been capable of maintaining or receiving an electrostatic charge, one solution has been to add a second substrate that does have the ability to receive, and at least temporarily maintain, an electrostatic charge for a sufficient amount of time to allow the substrate to be positioned generally around its desired location prior to the activation of the adhesive material. For example, in some apparatuses, the second substrate may be a discrete layer of polarized film. But the inclusion of a second substrate may increase material and handling costs, along with adding weight to the substrate. Furthermore, this second polarized film, if made of conventional electret films such as polypropylene, may have a tendency to distort when exposed to elevated temperatures, which may adversely impact the functionality of the substrate.

Thus, a need exists for a surface cover that may at least temporarily adhere to a mounting surface at a desired location, and, if needed, subsequently be re-positioned before the activation of an adhesive material. Moreover, a need exists for a surface cover having an polarized adhesive material that may allow for the at least temporary positioning, and subsequent re-positioning, of the surface cover along a mounting surface without damaging the substrate or adhesive capabilities of the adhesive material.

### BRIEF SUMMARY OF THE INVENTION

Embodiments of the present invention relate to a surface cover having a polarized adhesive material bonded or operably connected to at least a portion of a substrate. The adhesive material may be polarized before or after being bonded or operably connected to the substrate. Further, the polarized adhesive material may be continuously applied to the back portion of the substrate or at select locations. Prior to the activation of the polarized adhesive material, the surface cover may be positioned and aligned at the desired location, whereby the electrostatic charge carried by the polarized adhesive material may at least temporarily provide the necessary attraction force to maintain the positioning of the surface cover along the adjacent mounting surface. The polarized adhesive material may then be activated, such as through the use of heat or pressure, thereby allowing the surface cover to be supported by the activated adhesive material. The activation of the adhesive material may also result in the dissipation of the polarized charge so that the polarized charge may or may not be an integral part in the adhesive force that adheres the surface cover to the adjacent mounting surface. In one embodiment, the current invention can be used to replace products that rely on pressure sensitive adhesive material, such as, but not limited to, shelf liners, window tinting, and decals, or lamination applications, such as real or synthetic veneers on furniture.

### BRIEF DESCRIPTION OF SEVERAL VIEWS OF THE DRAWINGS

FIG. 1 illustrates a side perspective view of a surface cover having a substrate with at least a portion of the backside surface of the substrate being covered with a polarized adhesive material according to an embodiment of the present invention.

FIG. 2 illustrates a rear view of a surface cover having a substrate with a backside surface being at least partially covered with a polarized adhesive material according to an embodiment of the present invention.

FIG. 3 illustrates a rear view of a surface cover having a substrate with a polarized adhesive material being positioned in select locations on the backside surface of the substrate according to an embodiment of the present invention.

FIG. 4 illustrates a rear view of a surface cover having a substrate with a polarized adhesive material and non-polarized adhesive material being positioned in select locations on the backside surface of the substrate according to an embodiment of the present invention.

FIG. 5 illustrates a side view of a surface cover having a first substrate operably connected to a second substrate, and a polarized adhesive material according to an embodiment of the present invention.

The foregoing summary, as well as the following detailed description of the preferred embodiments of the present invention, will be better understood when read in conjunction with the appended drawings. For the purpose of illustrating the preferred embodiments of the present invention, the drawings depict embodiments that are presently preferred. It should be understood, however, that the present invention is not limited to the arrangements and instrumentality shown in the attached drawings.

### DETAILED DESCRIPTION OF THE INVENTION

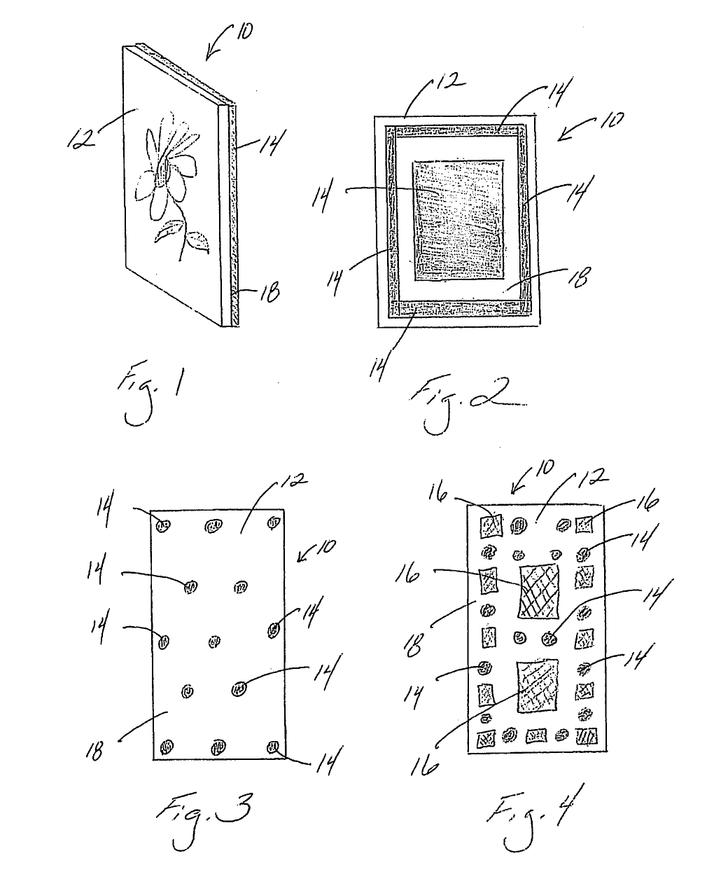

FIG. 1 illustrates a side perspective view of a surface cover 10 having a substrate 12 with at least a portion of the backside surface 18 of the substrate 12 being covered with a polarized adhesive material 14 according to an embodiment of the present invention. Suitable substrates 12 include wallpaper, boarder materials, paper, film, vinyl, fabric, polyester, and web materials, among others. Additionally, the materials selected for the substrate 12 may lack electret capabilities in that the substrate 12 has no or negligible electret capabilities. In other embodiments of the present invention, the substrate may have electret capabilities that may assist the polarized adhesive material 14 in adhering the surface cover 10 against at least a portion of the mounting surface prior to the activation of the polarized adhesive material 14.

The polarized adhesive material 14 may be bonded, embedded, or operably connected to the entire backside surface 18 of the substrate 12. In other embodiments, the polarized adhesive material 14 may be bonded or operably connected to only select areas of the substrate 18. Further, although FIG. 1 illustrates the polarized adhesive material 14 being bonded directly to the backside surface 18 of a single substrate 12, in other embodiments of the present invention the polarized adhesive material 14 may be applied to at least a portion of one substrate 12 or other backing material that is operably connected to at least one other substrate 12.

A number of different adhesive materials may be used in the present invention. In some embodiments, the adhesive material may be a heat activated adhesive material or a pressure activated adhesive material. Suitable heat activated adhesive materials include glues that are commonly used in the manufacturing of laminating film for the printing industry. Further, additives may be formulated into the adhesive material and/or substrate 12 to increase the receptivity and durability of the polarization charge.

The adhesive material used in the polarized adhesive material 14 may have properties that make it both a good electret and adhesive. Once charged with an electrostatic charge, the adhesive material becomes the polarized adhesive material 14. Examples of heat based adhesive materials may include polypropylenes, polyisobutylenes, cyclic olefin copolymers (COC), and members from the metallocene family of polymers, among others. In some embodiments, the adhesive material may have dielectric properties similar to that of polypropylene. An example of a commercially available polyisobutylene is Oppanol B200™, which is manufactured by BASF™. The properties of some of these materials are listed in the following table:

| | Polypropylene | Polyisobutylenes | COC |
|---|---|---|---|
| volume resistivity, | 10 * 16-10 * 18 | 1.00E+16 | 1.00E+17 |
| Ohm * m | | | |
| dielectric constant @ | 2.2-2.6 | 2.2 | 2.35 |
| 1 MHz | | | |
| dissipation factor | 0.0003-0.0005 | 0.005 | ≦0.0002 |

Additives, such as metallocene, among others, may be also formulated or added to the adhesive material to improve the electret and/or adhesive properties of the adhesive material. These additives may also be formulated to improve other characteristics or properties of the adhesive material, including the melting temperature, tackiness, and viscosity, among others. In some applications, such as when the surface cover 10 is traditional wallpaper, the adhesive, with or without the inclusion of any necessary additives, may need to be at least semi-flexible when in a solid state so that, when in use, the polarized adhesive material 14 does not prevent the surface cover 10 from being rolled.

The selection of adhesive materials and/or additives may also consider the temperature of the heat source used to activate the heat based materials, and any desire for that temperature to exceed the melting temperature of the adhesive material. For instance, in some applications, an iron or hair blower may provide heat at about 85 degrees Celsius for activation of the heat based adhesive material. In such applications, the selected or formulated adhesive material may have a melting temperature of less then about 85 degrees Celsius.

Because the charge carried by electrets may be dissipated or lost when the electret is exposed to temperatures above the glass temperature of the adhesive material, additives may also be included to increase glass temperatures. In some embodiments of the present invention, the glass temperature of the adhesive material may be about 60 degrees Celsius. Further, the glass transition temperature may be relatively close to the melting temperature.

Selection of an appropriate type of substrate 12 may consider such factors as the ability of the substrate 12 to withstand distortion when elevated to high temperatures during the activation of a hot melt adhesive material and/or exposure to humidity. For instance, during installation of the surface cover 10, the substrate 12 may be exposed to a hot heat source. Often the temperature of the heat source used to activate a hot melt adhesive is set at a temperature substantially above the melting temperature of the polarized adhesive material 14. For example, an iron used to activate a hot melt adhesive material may be set at temperatures in excess of 160 degrees Fahrenheit. The elevated temperature of the heat source may speed the transfer of heat and activate the polarized adhesive material 14 quickly and easily. However, such high temperatures may damage some types of substrates 12. For instance, films such as orientated polypropylene or polyester may warp and distort when exposed to temperatures that melt the polarized adhesive layer 14.

Other types of substrates 12 materials, such as paper, may be capable of withstanding such high temperatures without having problems with distortion, but are unable to resist distortion due to the absorption of humidity or being rolled up. Conversely, a polyester substrate 12 may resist dimensional instability from exposure to humidity, but distort under heat. A suitable material that may resist distortion or dimensional instability when exposed to high humidity and temperatures may include a nonwoven or woven fabric composed of cellulose and or synthetic fibers, and which has been treated with a chemical binder. An example of such a product is manufactured by Ahlstrom (product 16044 Regular Interlining). Alternatively, in accordance with one embodiment of the present invention, the substrate 12 may be operably connected to a second substrate that may act as a cover for the substrate 12 to prevent the substrate by being damaged by the direct exposure of the substrate 12 to the heating source and/or decrease the exposure of the substrate 12 to humidity. In another embodiment, the front surface of the substrate 12 may have a protective coating that prevents damage to the substrate 12 from direct exposure to the heat source and/or protects the substrate 12 from excessive exposure to humidity.

Application of adhesive material to the substrate 12 may be achieved through extrusion coating. In such a process, pellets of dry adhesive material may be heated and forced through a die that thins out the adhesive material into a continuous web of semi-molten adhesive material. In some applications, the molten adhesive material may then be applied to the substrate 12 while the substrate 12 is part of a continuous web of film via a nip roller. The temperature of the molten adhesive material when it is applied to the substrate 12 may at least in part be dependent on the properties of the polarized adhesive material 14 and/or substrate 12.

Polarization of the adhesive material may occur when the adhesive material is in a molten state through the use of a large polarizing electric current. Through polarization of the molten adhesive material, an electric current may orientate molecules in the molten adhesive material so that they are all positively or negatively aligned in the same direction. However, other adhesive materials may be electrostatically charged when the adhesive material is in a solid state. For example, the electrostatic charge may be applied to the adhesive material when it is in a molten state immediately after the adhesive material is extruded through a die, or, alternatively, after the adhesive material has been re-solidified on the substrate 12 following reaching a nip/chill roller. Determination of whether to charge the adhesive material when the adhesive material is in a molten or solid state may depend on a variety of factors, including, but not limited to, the material of the substrate 12.

In application, the polarized adhesive material 14 may at least temporarily adhere the surface cover 10, and more particularly the substrate 12, to an adjacent mounting surface. Temporary reliance on the adherence created by the differences between the polarities of the polarized adhesive material 14 and the mounting surface may allow the surface cover 10, and any adjacent or adjoining surface covers, to be installed and repositioned (i.e., via removal or sliding) at desired locations prior to final installation. For some polarized adhesive materials, final installation may involve the activation and setting or curing of the activation of the polarized adhesive material against the mounting surface.

Once the surface cover 10 is positioned against the mounting surface at its desired location, the polarized adhesive material 14 may be activated. In the illustrated embodiment, activation of a hot melt polarized adhesive material 14 may involve the application of a heat source, such as a iron or blow-drier, to the surface cover 10, which may result in a rise in temperature in the polarized adhesive material 14 on the backside 18 of the substrate 12. For example, some hot melt adhesives require a minimum activation temperature of 65 degrees Celsius. The rise in temperature may result in at least a portion of a heat based polarized adhesive material 14 being transformed into a molten state. At some point after the removal of the heat source, the temperature of the heat activated polarized adhesive material 14 may decreased, whereby molten polarized adhesive material may set or cure against both the substrate 12 or other portions of the polarized adhesive material 14 and the mounting surface. In some embodiments of the present invention, activation of the polarized adhesive material 14 may significantly dissipate or remove the electrostatic charge of the polarized adhesive material 14 so that the “sticking” or adhering engagement created by the activated adhesive material, and not the electrostatic charge, may provide a significant portion, if not all, of the adhesive force required to maintain the substrate 12 at its desired location.

As previously mentioned, the adhesive material, before or after being polarized, may be positioned or coated onto a substantial portion of the substrate 12, such as the backside of the substrate 12. However, in other embodiments, the polarized adhesive material 14 may be selectively placed along the substrate 12. For example, FIG. 2 illustrates a rear view of a surface cover 10 having a substrate 12 with a backside surface 18 being at least partially covered with a polarized adhesive material 14 according to an embodiment of the present invention. Selective placement of the polarized adhesive material 14 may reduce manufacturing and material costs of the surface cover 10. In another example, the polarized adhesive material 14 may be applied to the backside surface 18 of the substrate 12 in a grid or lined pattern.

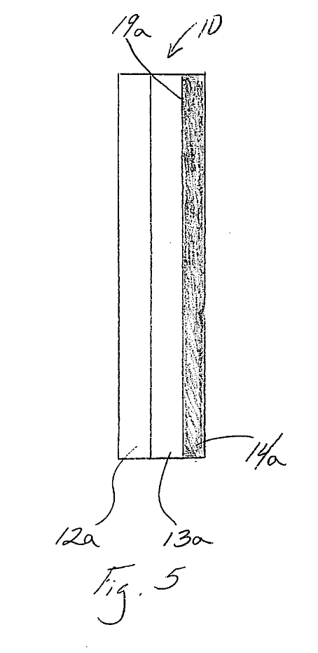

FIG. 3 illustrates a rear view of a surface cover 10 having a substrate 12 with a polarized adhesive material 14 being positioned in select locations on the backside surface 18 of the substrate 12 according to an embodiment of the present invention. In such an embodiment, adhesive material that is polarized or capable of carrying a polarized charge may be placed in select positions on the substrate 12, such as the corners, edges, and/or center region on the backside 18 of the substrate 12.

FIG. 4 illustrates a rear view of a surface cover 10 having a substrate 12 with a polarized adhesive material 14 and non-polarized adhesive material 16 being positioned in select locations on the backside surface 18 of the substrate 12 according to an embodiment of the present invention. In such embodiments, the amount and location of the polarized adhesive material 14 may be such that the substrate 12 may still be able to at least temporarily positioned along or against an adjacent mounting surface before the introduction of heat to activate either the polarized adhesive material 14 or the non-polarized adhesive material 16. The non-polarized adhesive material 16, such as, but not limited to, heat or pressure activated adhesive materials, may be placed at other locations on the substrate 12 that are not occupied by the polarized adhesive material 14. In another embodiment, the polarized adhesive material 14 may be placed on top of, or at least partially overlap, at least a portion of the non-polarized adhesive materials 16. But again, in such embodiments, the amount and location of the polarized adhesive material 14 may be such that the substrate 12 may still be able to at least temporarily be positioned along or against the adjacent mounting surface before the activation of the polarized adhesive material 14 and/or the activation of non-polarized adhesive material 16.

FIG. 5 illustrates a side view of a surface cover 10 having a first substrate 12a operably connected to a second substrate 13a, and a polarized adhesive material 14a according to an embodiment of the present invention. The first substrate 12a and the second substrate 13a may be operably connected to each other through the use of an adhesive, such as, but not limited to, glues and epoxies. In such an embodiment, both the first and second substrates 12a, 13a, may or may not be capable of receiving or maintaining any electric charge. For example, the first substrate 12a and/or second substrate 13a may be paper, fabric, film, or polyester materials that have little, if any, electret capabilities. Moreover, when both the first and second substrates have no electret capabilities or negligible electret capabilities, the polarized adhesive material 14a may provide a sufficient polarized charge to at least temporarily adhere the surface cover 10 at least generally in the desired location until the activation of the polarized adhesive material 14a. In another embodiment, the material selected for the first substrate 12a and/or second substrate 13a may have at least some electric capabilities that may assist with polarized adhesive material 14a in at least partially securing the surface cover 10 against the mounting surface before activation of the polarized adhesive material 14a.

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiment disclosed, but that the invention will include all embodiments falling within the scope of the appended claims.

1. A surface cover comprising:
a. at least one substrate having a face portion and a back portion; and
b. an adhesive material operably connected to at least a portion of the at least one substrate, at least a portion of the adhesive material receiving an electrostatic charge to create a polarized adhesive material, the polarized adhesive material being configured and electrostatically charged to allow the surface cover to at least temporarily adhere to an adjacent mounting surface before the activation of the adhesive material.

2. The surface cover of claim 1 wherein the at least one substrate has no electret capabilities.

3. The surface cover of claim 1 wherein the at least one substrate has insufficient electret capabilities to assist the polarized adhesive material to at least temporarily adhere to an adjacent mounting surface before the activation of the adhesive material.

4. The surface cover of claim 1 including a second substrate, the second substrate operably connected to the at least one substrate, the second substrate capable of being polarized.

5. The surface cover of claim 1 wherein the adhesive material is a hot melt adhesive material.

6. The surface cover of claim 5 including an additive included in the hot melt adhesive material, the additive capable of receiving an electrostatic charge to create a polarized additive, the additive improving the adhesive ability of the polarized based adhesive material to hold an electrostatic charge.

7. The surface cover of claim 5 including an additive included in the hot melt adhesive material, the additive reducing the melting temperature of the polarized adhesive material.

8. The surface cover of claim 1 wherein the substrate is a nonwoven or woven fabric composed of cellulose and or synthetic fibers, and which has been treated with a chemical binder.

9. The surface cover of claim 1 including a non-polarized adhesive material bonded to at least a portion of the at least one substrate.

10. A surface cover comprising:
a. at least one substrate having a face portion and a back portion, the at least one substrate lacking electret capabilities; and
b. an adhesive material bonded to at least a portion of the back portion of the at least one substrate, at least a portion of the adhesive material receiving an electrostatic charge to create a polarized adhesive material, the adhesive material being a hot melt adhesive material, the polarized adhesive material having a different polarity than an adjacent mounting surface, the polarized adhesive material being configured and electrostatically charged to allow the surface cover to at least temporarily adhere to the adjacent mounting surface before activation of the adhesive material.

11. The surface cover of claim 10 wherein the at least one substrate has no electret capabilities.

12. The surface cover of claim 10 wherein the at least one substrate has insufficient electret capabilities to assist the polarized adhesive material to at least temporarily adhere to an adjacent mounting surface before the activation of the adhesive material.

13. The surface cover of claim 10 including a second substrate, the second substrate operably connected to the at least one substrate, the second substrate capable of being polarized.

14. The surface cover of claim 10 wherein the adhesive material is a hot melt adhesive material.

15. The surface cover of claim 14 including an additive included in the hot melt adhesive material, the additive capable of receiving an electrostatic charge to create a polarized additive, the additive improving the adhesive ability of the polarized based adhesive material to hold an electrostatic charge.

16. The surface cover of claim 14 including an additive included in the hot melt adhesive material, the additive reducing the melting temperature of the polarized adhesive material.

17. The surface cover of claim 10 wherein the substrate is a nonwoven or woven fabric composed of cellulose and or synthetic fibers, and which has been treated with a chemical binder.

18. The surface cover of claim 10 including a non-polarized adhesive material bonded to at least a portion of the at least one substrate.

19. A surface cover comprising:
a. at least one substrate having a face portion and a back portion, the at least one substrate having no electret capabilities; and
b. an adhesive material bonded to at least a portion of the back portion of the at least one substrate, at least a portion of the adhesive material receiving an electrostatic charge to create a polarized adhesive material, the adhesive material being a hot melt adhesive material, the polarized adhesive material having different polarity of an adjacent mounting surface, the polarized adhesive material being configured and electrostatically charged to allow the surface cover to at least temporarily adhere to the adjacent mounting surface before activation of the adhesive material.

20. The surface cover of claim 19 including a second substrate, the second substrate operably connected to the at least one substrate, the second substrate capable of being polarized.

21. The surface cover of claim 19 wherein the adhesive material is a hot melt adhesive material.

22. The surface cover of claim 21 including an additive included in the hot melt adhesive material, the additive capable of receiving an electrostatic charge to create a polarized additive, the additive improving the adhesive ability of the polarized based adhesive material to hold an electrostatic charge.

23. The surface cover of claim 21 including an additive included in the hot melt adhesive material, the additive reducing the melting temperature of the polarized adhesive material.

24. The surface cover of claim 21 wherein the hot melt adhesive material includes a polypropylene.

25. The surface cover of claim 21 wherein the hot melt adhesive material includes a polyisobutylene.

26. The surface cover of claim 21 wherein the hot melt adhesive material includes a cyclic olefin copolymer.

27. The surface cover of claim 21 wherein the hot melt adhesive material includes a member from the metallocene family of polymers.

28. The surface cover of claim 19 wherein the substrate is a nonwoven or woven fabric composed of cellulose and or synthetic fibers, and which has been treated with a chemical binder.

29. The surface cover of claim 19 including a non-polarized adhesive material bonded to at least a portion of the at least one substrate.
